(19) United States
(12) Patent Application Publication
(10) Pub. No.: US 2011/0164347 A1
(43) Pub. Date: Jul. 7, 2011

(54) Package for an Electrical Device

(76) Inventors: Phillip Brett Aitchison, New South Wales (AU); Alexander Bilyk, New South Wales (AU); Allan Godsk Larsen, New South Wales (AU); John Chi Hung Nguyen, New South Wales (AU); Andrzej Kucharzewski, New South Wales (AU)

(21) Appl. No.: 13/062,785

(22) PCT Filed: Sep. 9, 2009
(86) PCT No.: PCT/AU09/01181

§ 371 Date: Mar. 8, 2011

(30) Foreign Application Priority Data
Sep. 9, 2008 (AU) 2008-904696

(51) Int. Cl. H01G 9/155; H05K 5/06; H05K 5/00

(52) U.S. Cl. 361/502; 174/50.54; 174/520

(57) ABSTRACT

A generally prismatic package (1) for an electrical device in the form of supercapacitive element (2) having an electrical property with a predetermined value. Package (1) includes an insulating element in the form of a generally rectangular-prismatic liquid crystal polymer (LCP) housing (3) for supporting element (2). More specifically, element (2) is mounted to the insulating element such that, following surface mounting of element (2) to a substrate, in the form of a printed circuit board (not shown), the electrical property remains within a predetermined tolerance.

### FIELD OF THE INVENTION

The present invention relates to an electrical device and in particular to a package for an electrical device.

The invention has been primarily developed for facilitating the surface mounting of an electrical device to a substrate and will be described hereinafter with reference to that application. However, it will be appreciated that the invention is not limited to this particular field of use and is also applicable to electrical devices that are other than surface mounted to a substrate.

The disclosure of the present application also incorporates by reference the applicant's co-pending PCT applications filed on the same date as the present application with the Australian Patent Office acting as an International Receiving Office, where the co-pending applications are entitled “A Charge Storage Device” (Attorney reference 55816WOP00) and “A Package for an Electrical Device” (Attorney reference 55818WOP00).

### BACKGROUND OF THE INVENTION

Any discussion of the prior art throughout the specification should in no way be considered as an admission that such prior art is widely known or forms part of common general knowledge in the field.

It is known to use surface mount technology (SMT) to mount a number of surface mount components (SMC) to a printed circuit board (PCB) to define a surface mount device (SMD). The SMCs are selected from the wide variety available. One of the key advantages of SMT is a size reduction of the SMD relative to a corresponding electronic device making use of through-hole technology.

Due to SMT typically being automated, there is a need for SMCs to be particularly robust. This has generally excluded certain electronic components, such as supercapacitors, from SMT processes. And even if the supercapacitors are able to withstand the SMT process, that process often impacts upon the operational lifetime of the supercapacitor.

Another factor that often makes supercapacitors undesirable in SMD applications is the physical size of the supercapacitor relative to the capacitance provided and, often, the large variation in the external dimensions of supercapacitors.

### SUMMARY OF THE INVENTION

It is an object of the present invention to overcome or ameliorate at least one of the disadvantages of the prior art, or to provide a useful alternative.

According to a first aspect of the present invention there is provided a package for an electrical device having an electrical property with a predetermined value, the package including an insulating element for supporting the device such that, following surface mounting of the device to a substrate, the predetermined value remains within a predetermined tolerance.

In an embodiment, the electrical device includes packaging that is sealed and, following surface mounting of the device to the substrate, the packaging remains sealed.

In an embodiment, the device includes a supercapacitive element that is mounted to the insulating element and at least two terminals that extend from the supercapacitive element, the package including at least two leads for electrically connecting the terminals with the substrate. In another embodiment, the insulating element is a housing having both an interior for containing the supercapacitive element and an exterior, wherein the leads extend from the interior to the exterior.

In an embodiment, the electrical property is selected from the group including: equivalent series resistance (ESR) and capacitance (C).

In an embodiment, the predetermined tolerance is ±100% of the predetermined value. In another embodiment, the predetermined tolerance is ±50% of the predetermined value. In yet another embodiment, wherein the predetermined tolerance is ±20% of the predetermined value. In yet another embodiment, the predetermined tolerance is ±10% of the predetermined value.

In an embodiment, the insulating element contains the temperature within the interior to less than 230° C. during the surface mounting of the device to the substrate. In another embodiment, the insulating element contains the temperature within the interior to less than 200° C. during the surface mounting of ₜhe device to the substrate. In yet another embodiment, the insulating element contains the temperature within the interior to less than 180° C. during the surface mounting of the device to the substrate.

In an embodiment, the insulating element increases the thermal capacity of the device.

In an embodiment, the insulating element increases the thermal barrier between the substrate and the device.

In an embodiment, the electrical property is the equivalent series resistance and the tolerance of the predetermined value is ±20%.

In an embodiment, the insulating element has a thermal conductivity of less than or equal to about 0.8 W/(mK). In another embodiment, the insulating element has a thermal conductivity of less than or equal to about 0.5 W/(mK). In yet another embodiment, the insulating element has a thermal conductivity of less than or equal to about 0.2 W/(mK).

In an embodiment, the insulating element has a volumetric specific heat capacity of at least about 0.5 kJ/kg/K. In another embodiment, the insulating element has a volumetric specific heat capacity of at least about 1 kJ/kg/K. In yet another embodiment, the insulating element has a volumetric specific heat capacity of at least about 1.5 kJ/kg/K.

According to a second aspect of the present invention there is provided an energy storage device having an electrical property with a predetermined value, the device including:

a supercapacitive element;

at least two terminals extending from the supercapacitive element; and

an insulating element for supporting the supercapacitive element such that, following surface mounting of the device to a substrate, the predetermined value remains within a predetermined tolerance.

According to a third aspect of the present invention there is provided a method of surface mounting an energy storage device having an electrical property with a predetermined value, the method including the step of supporting the device with an insulating element such that, following surface mounting of the device to a substrate, the predetermined value remains within a predetermined tolerance.

In an embodiment, the insulating element includes one or more of: Nomex™ material; and silicone.

According to a fourth aspect of the present invention there is provided a package for an energy storage device having a supercapacitive element and at least two terminals extending from the element, the supercapacitive element having an electrical property of a predetermined value, wherein the package includes an insulating element for supporting the supercapacitor element such that, following surface mounting of the terminals to a substrate, the at least one electrical property remains within a predetermined tolerance.

According to a further aspect of the invention there is provided a package for an electrical device having at least two terminals and containing a liquid with a predetermined boiling point, the package including:

at least one sidewall for defining an interior for receiving the electrical device;

at least one access point in the sidewall;

leads that extend between respective first ends and second ends, wherein: the first ends are disposed within the interior and are electrically connected to respective terminals; and the leads extend through the access point such that the free ends are external to the package; and

an insulator for maintaining the electrolyte below the boiling point during the surface mounting of the free ends to a substrate.

According to a further aspect of the invention there is provided a method for packaging an electrical device having at least two terminals and containing a liquid with a predetermined boiling point, the method including:

defining with at least one sidewall an interior for receiving the electrical device;

providing at least one access point in the sidewall;

providing leads that extend between respective first ends and second ends;

disposing the first ends within the interior;

electrically connecting the first ends to respective terminals;

allowing the leads to extend through the access point such that the free ends are external to the package; and

providing an insulator for maintaining the electrolyte below the boiling point during the surface mounting of the free ends to a substrate.

According to a further aspect of the invention there is provided a surface mount component (SMC) including a package according to an aspect of the invention.

According to a further aspect of the invention there is provided a surface mount technology circuit including one or more SMC's of the immediately preceding aspect of the invention.

According to a further aspect of the invention there is provided an electronic device including one or more circuits of the immediately preceding aspect of the invention.

According to a further aspect of the invention there is provided a surface mount component (SMC) including:

at least one sidewall for defining an interior for receiving one or more electrical devices;

at least two leads extending from the interior to an exterior for allowing external electrical contact with the one or more electrical devices; and

an insulator for maintaining the temperature of the interior below about 230° C. while the terminals are surface mounted to a substrate.

In an embodiment, the temperature of the interior is maintained below about 200° C. In another embodiment the temperature of the interior is maintained below about 180° C.

In an embodiment, the sidewall and the insulator are formed from a liquid crystal polymer. Preferably, the sidewall and the insulator are integrally formed.

In an embodiment, the footprint of the SMC is no more than about 600 mm².

In an embodiment, the footprint of the SMC is no more than about 400 mm².

In an embodiment, the height of the SMC is no more than about 2 mm.

In an embodiment, the height of the SMC is no more than about 1.4 mm.

In an embodiment, the thickness of the at least one sidewall is less than about 0.16 mm.

In an embodiment, the thickness of the at least one sidewall is less than about 0.11 mm.

In an embodiment, the thickness of the lid is no more than about 300 microns.

In an embodiment, the heat deflection temperature of the sidewall is about 260° C.

In an embodiment, the heat deflection temperature of the sidewall is about 280° C.

According to a further aspect of the invention there is provided an electronic device including one more electrical devices, wherein at least one of the electrical devices are disposed within a package of the first aspect.

In an embodiment, the electronic device is selected from the following list: a desktop computer; a laptop computer; a net-book computer; a cellular telephone, a camera; a PDA; another consumer electronic device.

According to a further aspect of the invention there is provided a package for an electrical device having an electrical property with a predetermined value, the package including an insulating element for supporting the device such that, following surface mounting of the device to a substrate, the electrical property remains within a predetermined tolerance.

According to a further aspect of the invention there is provided an energy storage device having an electrical property with a predetermined value, the device including:

a supercapacitive element;

at least two terminals extending from the supercapacitive element; and

an insulating element for supporting the supercapacitive element such that, following surface mounting of the device to a substrate, the electrical property remains within a predetermined tolerance.

### BRIEF DESCRIPTION OF THE DRAWINGS

Preferred embodiments of the invention will now be described, by way of example only, with reference to the accompanying drawings in which:

FIG. 1 is a perspective view of a package;

FIG. 2 is an exploded perspective view of the package of FIG. 1 without a supercapacitive element;

FIG. 3 is a top view of the package of FIG. 1;

FIG. 4 is a sectional view taken along line 4-4 of FIG. 3;

FIG. 5 is a side view of the package of FIG. 1;

FIG. 6 is a side view of the package of FIG. 1;

FIG. 7 is a sectional view taken along line 7-7 of FIG. 5;

FIG. 8 is a similar view to that of FIG. 4 showing an alternate embodiment of the package;

FIG. 9 is a perspective view, similar to FIG. 1, of another embodiment of the package;

FIG. 10 is an exploded perspective view, similar to FIG. 2, of the package of FIG. 9 without a supercapacitive element;

FIG. 11 is a side view, similar to FIG. 5, of another embodiment of the package;

FIG. 12 is an end view of the package of FIG. 11; and

FIG. 13 is an enlarged fragmentary sectional view taken along line 13-13 of FIG. 12.

The drawings are provided for illustrative purposes only and are not to scale.

### PREFERRED EMBODIMENTS OF THE INVENTION

It is appreciated that corresponding reference numerals will denote corresponding features in the different embodiments described.

The embodiments of the invention have been primarily developed for a supercapacitive device and the description below has reference to such devices. However, it will be appreciated that the invention is not limited to supercapacitive devices and, for example, may be used for energy storage devices such as batteries and capacitors, and other electrical devices such as MEMS electronic devices, MEMS electromechanical devices, MEMS electrochemical devices, integrated circuit devices (IC's), and hybrids of any of the preceding electrical devices, amongst others.

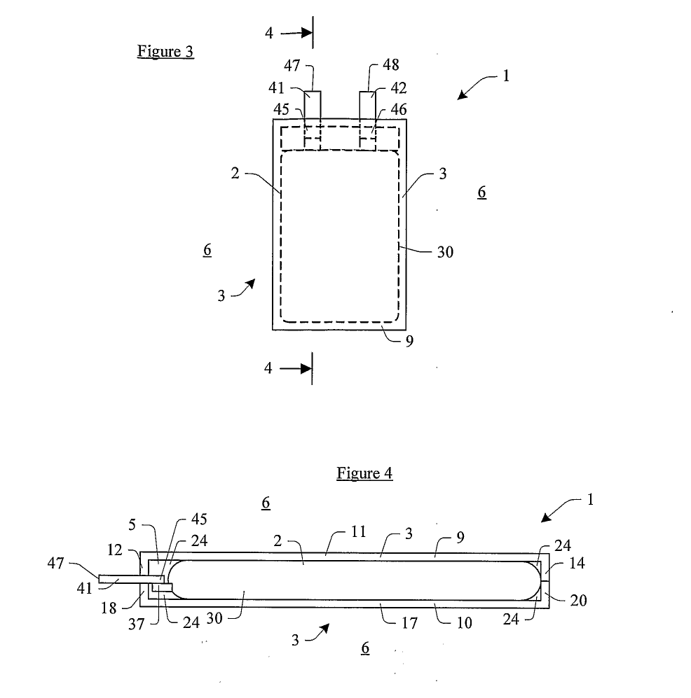

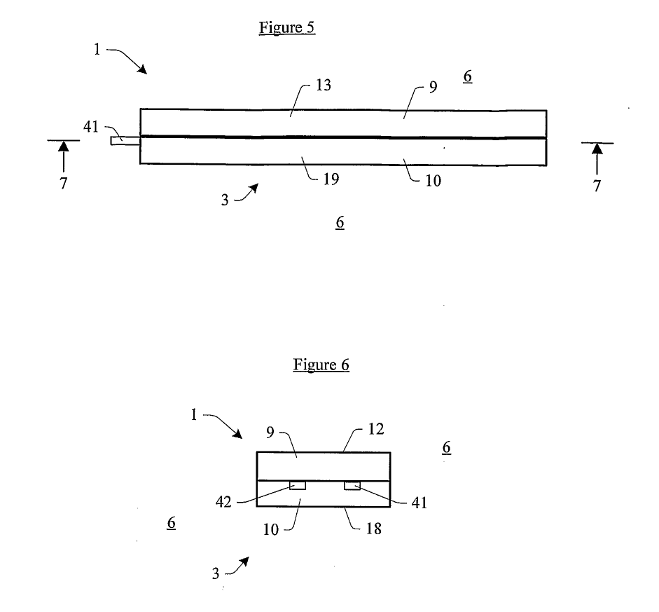

Referring initially to FIGS. 1 to 7 there is illustrated a generally prismatic package 1 for an electrical device in the form of supercapacitive element 2 having an electrical property with a predetermined value. Package 1 includes an insulating element in the form of a generally rectangular-prismatic liquid crystal polymer (LCP) housing 3 for supporting element 2. More specifically, element 2 is mounted to the insulating element such that, following surface mounting of element 2 to a substrate, in the form of a printed circuit board (not shown), the electrical property remains within a predetermined tolerance.

It will be appreciated that in some embodiments a plurality of electrical properties are assessed pre and post surface mounting of the element 2 to a PCB to determine if they fall within respective predetermined tolerances.

Housing 3 has both a rectangular-prismatic interior 5 for containing element 2, and an exterior 6. Housing 3 is formed of an upper section 9 and a like and opposed lower section 10 that, as shown, collectively envelope element 2. Section 9 includes a substantially planar rectangular top wall 11 and four sidewalls 12, 13, 14 and 15 that extend from wall 11 to collectively define a continuous downwardly facing abutment surface 16. Wall 11 and sidewalls 12, 13, 14 and 15 are integrally formed. Section 10 includes a substantially planar rectangular base 17 and four sidewalls 18, 19, 20 and 21 that extend from base 17 to collectively define an upwardly facing continuous abutment surface 22. Base 17 and sidewalls 18, 19, 20 and 21 are integrally formed. Surface 16 is complementarily, co-extensively and sealingly engaged with surface 22 such interior 5 is also sealed. In other embodiments, surfaces 16 and 22 are fixedly but not sealingly engaged.

Housing 3 extends longitudinally between sidewalls 12 and 14 and transversely between sidewalls 13 and 15 to define a footprint for the package.

The use of the relative terms “upper” and “lower” and the like are used with reference to the drawings in this specification to assist the addressee understand the embodiments. It will be appreciated, however, that these terms are not used in an absolute sense and, in practice, the upper section need to be physically located at a greater altitude than the lower section.

In other embodiments, wall 11 and respective sidewalls 12, 13, 14 and 15, and base 17 and respective sidewalls 18, 19, 20 and 21, are other than integrally formed. In one such embodiment, the base and sidewalls are heat welded to each other.

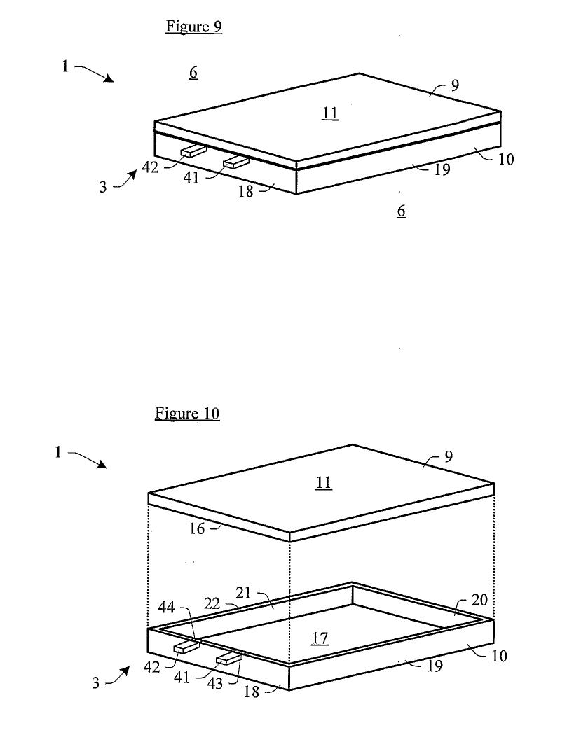

In other embodiments sections 9 and 10 are differently shaped to each other. For example, in the embodiment shown in FIGS. 9 and 10, section 9 takes the form of a substantially planar lid and section 10 takes the form of a container to which the lid is applied.

As best shown in FIGS. 4 and 7, the interior 5 of housing 3 is not completely contiguous with element 2. That is, there is a plurality of voids (each denoted by reference numeral 24) spaced within interior 5 of housing 3. In this embodiment voids 24 are air filled. However, in other embodiments, voids 24 are at least partially filled with one or more other materials to provide increased thermal insulation or increased thermal load for housing 3. For example, in some embodiments the one or other materials includes a phase change material (PCM) or a combination of phase change materials. Examples of suitable PCMs include Mannitol and Dulcitol, although other sugar alcohols are also suitable. In some embodiments, the PCM is mixed 1:1 with silicone to form a paste/gel that is then applied to element 2 and/or housing 3 to fill voids 24.

It is also appreciated that in other embodiments, housing 3 only partially contains and envelops element 2. In various embodiments the degree of containment and envelopment of element 2 by housing 3 varies according to particular application requirements. For example, in one embodiment, use is made only one or another subset of the sidewalls and the base.

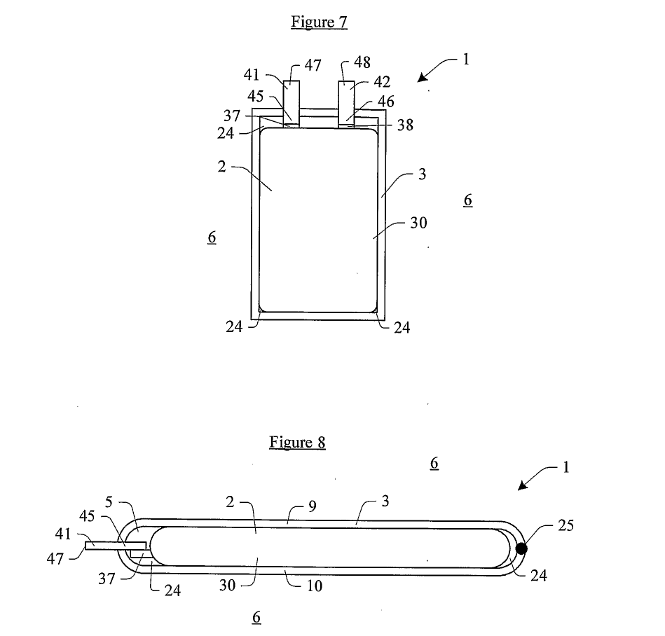

In other embodiments, housing 3 is formed of other than two sections. For example, in the embodiment shown in FIG. 8, sections 9 and 10 are integrally formed and folded about a transverse axis 25 to longitudinally extend back along each.

Element 2 is a supercapacitor 30 that includes two terminals 37 and 38 that extend from the supercapacitor 30 for allowing electrical connection to supercapacitor 30. Supercapacitor 30 is formed from layers of aluminium coated with high surface areas carbon and separated by an ionically conductive but electrically insulating material such as porous plastic or paper. The aluminium layers are folded or rolled together or segmented and stacked: to define a positive electrode and a negative electrode; and, typically, to maximise the opposed surface area between the layers. Supercapacitor 30 is saturated in an electrolyte and can operate continuously at up to 3 Volts. In other embodiments alternative operating voltages are accommodated.

The electrolyte used in supercapacitor 30 is, in some embodiments, one or more salts dissolved in one or more non-aqueous solvents. For example, TEATFB dissolved in acetonitrile, TEMATFB dissolved in propionitrile, or the like. Other embodiments include an ionic liquid such as, for example, EMITFB, EMITFMS, EMITFSI, and the like. In further embodiments use is made of a salt dissolved in an organo-silicone, while in still further embodiments use is made of a mixture of two or more of the above.

More specific examples of electrolytes are disclosed in the international patent application having the publication no. WO 2007/101303 and the applicant's co-pending application filed on the same date as the present application and entitled “A Charge Storage Device” (Attorney's reference 55816WOP00). The disclosure within these applications is incorporated into the present application by way of cross-reference.

In other embodiments the supercapacitive element includes more than one supercapacitor in parallel or series. In still further embodiments, the supercapacitive element includes a hybrid device including both at least one supercapacitor and at least one electrochemical energy storage cell in parallel or series.

Typical embodiments of element 2 include dimensions in the range of:
15 mm to 20 mm for width.
20 mm to 39 mm for length.
1 mm to 3.3 mm for height/thickness.

In other embodiments elements of different dimension are used to accommodate different footprints and to provide different electrical characteristics.

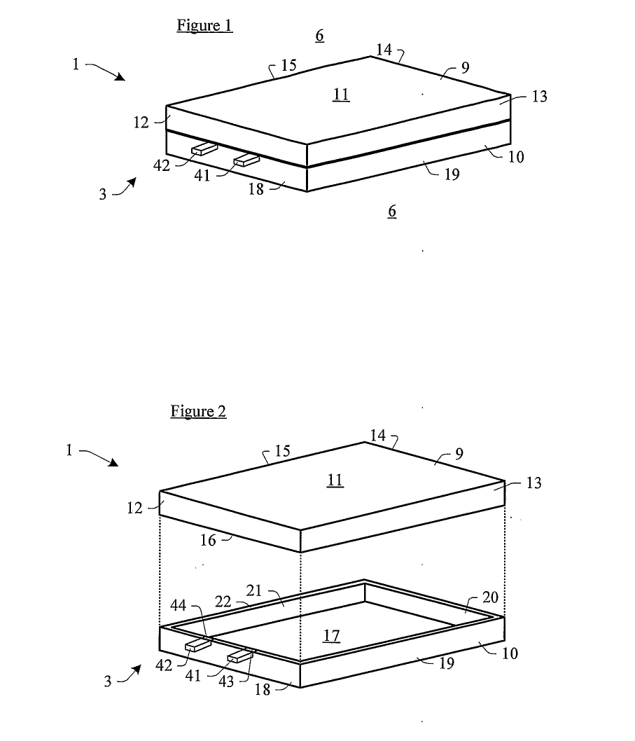

As shown in FIGS. 2 and 4, package 1 includes two leads 41 and 42 that extend from interior 5 to exterior 6 for electrically connecting respective terminals 37 and 38 with the substrate (not shown). Leads 41 and 42 extend through respective transversely spaced apart receiving recesses 43 and 44 in sidewall 18. In other embodiments recesses 43 and 44 are in one of wall 11, sidewalls 12, 13, 14, 15, 19, 20 and 21, or base 17. In yet other embodiments, recesses 43 and 44 are each in a different one of wall 11, sidewalls 12, 13, 14, 15, 18, 19, 20 and 21, and base 17.

In other embodiments package 1 has other than two leads.

Leads 41 and 42 include respective interior contacts 45 and 46 for electrically connecting with terminals 37 and 38 and two exterior contacts 47 and 48 for electrically connecting with the PCB (not shown).

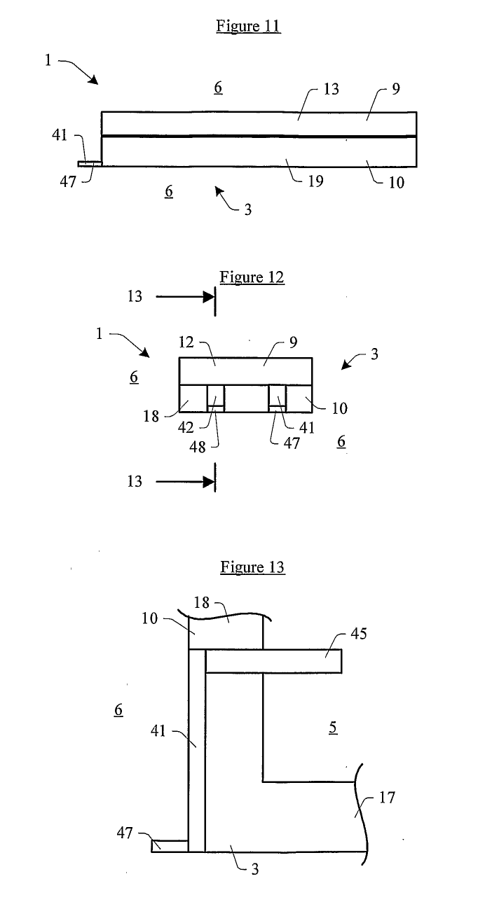

In other embodiments differently shaped leads 41 and 42 are used. By way of example only, one such embodiment is illustrated in FIGS. 11 to 13, where leads 41 and 42 extend vertically down sidewall 18 and exterior contacts 47 and 48 are foot portions. It will be appreciated by those skilled in the art, given the benefit of the teaching herein, that many other shapes and configurations for the leads are available.

In other embodiments, element 2 includes multiple supercapacitors. In yet other embodiments, element 2 is other than a supercapacitor. For example in various embodiments, element 2 is one or more of the following SMC's:
Energy storage devices such as one or more batteries, capacitors, supercapacitors or hybrids of these devices.
MEMS devices such as one or more MEMS electronic devices and/or one or more MEMS electromechanical devices and/or one or more MEMS electrochemical devices.
Integrated circuit devices (IC's).
Combinations of the above.

Element 2 is one of a plurality of SMC's that is to be surface mounted to a PCB to form a SMD. The PCB has a finite area upon which the SMC's are able to be mounted and, hence, importance is placed on the utilisation of small SMC's. It is, as a result, preferable for housing 3 to have as small a footprint as possible for the available height, and to provide a high capacitance and a low ESR for the given footprint and a high specific capacitance and low specific ESR. It will be appreciated that the specific capacitance and the specific ESR are the capacitance and ESR per unit volume for the packaged supercapacitor. The dimensions of housing 3 are governed by the following factors:
The size of element 2.
The type of material used to construct housing 3, which defines how thick housing 3 will be due to structural and thermal requirements for effective operation of housing 3.

The external dimensions of the exterior of housing 3 are:
Length: about 28 mm between sidewalls 12 and 14.
Width: about 20 mm between sidewalls 13 and 15.
Height: about 3 mm between wall 11 and base 17.

Therefore the footprint of housing 3, excluding leads 41 and 42, is about 560 mm² and the total package volume about 1,680 mm³. Leads 41 and 42 extend out about 3 mm from the exterior surface of sidewall 18. Therefore the total footprint, that is the footprint of housing 3 including leads 41 and 42, is about 620 mm² and the total package volume about 1,860 mm³. When calculating the specific capacitance and specific ESR the volume used is typically that of the package sans leads.

In this embodiment the thickness of each of wall 11, sidewalls 12, 13, 14, 15, 18, 19, 20 and 21, and base 17 are substantially equal and uniform. The thickness of each of wall 11, sidewalls 12, 13, 14, 15, 18, 19, 20 and 21, and base 17 is about 200 microns. In another embodiment, the thickness of each of wall 11, sidewalls 12, 13, 14, 15, 18, 19, 20 and 21, and base 17 is less than about 250 microns. Preferably, the thickness of each of wall 11, sidewalls 12, 13, 14, 15, 18, 19, 20 and 21, and base 17 is less than about 1 mm.

It will be appreciated that the thickness of the walls is preferably as low as possible to minimise the use of materials and to maximise the dimensions of interior 5 However, there are countervailing factors that dictate thicker walls, including the need for structural strength, and the desire for housing 3 to provide high thermal shielding and high thermal mass.

Where the design factors dictate a need for a thicker wall, base or sidewalls, it is possible to selectively increase the thickness of one or more of the wall, the base and the sidewalls, rather than increasing the thickness of all.

In other embodiments use is made of different dimensions for housing 3. For example, another housing (not shown) includes exterior dimension of 24×16×2 mm. It will be appreciated that many other dimensions are available.

In other embodiments, wall 11, sidewalls 12, 13, 14, 15, 18, 19, 20 and 21, and base 17 are not uniform in thickness. For example, in one embodiment, sidewalls 12 and 18 are thicker than wall 11, sidewalls 13, 14, 15, 19, 20 and 21, and base 17. This provides greater structural strength to housing 3 and greater thermal insulation to element 2 during the soldering of contacts 41 and 42 to the PCB. That is, where it is know that localised heating or compressive loading will occur, the thickness of the wall, base and sidewall are selectively increased. Another example includes where housing 3 is mounted on the PCB adjacent to, for example, a heat generating component such as a CPU or a current gain transistor. The thickness of selected sidewalls, base and wall is increased (or decreased) to account for the specific circuit.

SMT processes such as the mounting of element 2 to the PCB involves, amongst others, exposing the SMC to temperatures of up to about 260° C. for up to about 90 seconds. As mentioned above, this can detrimentally affect the subsequent performance and operational lifetime of element 2. The use of housing 3 substantially obviates this affect.

It is appreciated that in other embodiments, housing 3 is formed of other than liquid crystal polymer. For example, different materials are used in different embodiments to utilise certain preferential characteristics of certain materials. Some examples of other materials are set out further below and others are included in the cross-reference patent specifications. It will also be appreciated that while the preference is to the use of a single material, package 1 is able to be constructed from a combination of materials. The choice of material or materials for housing 3 depends on, amongst others, whether element 2 includes a structural or non-structural barrier. Examples of structural barriers include:
Laminates used for the packaging of batteries.
Casings formed of one or more of: a metal; a plastics; and a ceramic.

In embodiments to be used with structural barriers in place, package 1 provides thermal protection only.

Examples of non-structural barriers include:
Coatings such as parylene, silicon dioxide (SiO₂), di-aluminium trioxide (Al₂O₃).
Metal foils.

In embodiments to be used with non-structural barriers in place, package 1 provides both structural protection and thermal protection. Structural considerations include dimensional stability, form, and physical and/or chemical protection from the environment.

Housing 3 provides thermal robustness to element 2. Accordingly, housing 3 is formed of one or more materials that generally provide stability to the element against the heating associated with SMT, thereby allowing the predetermined value of the electrical property to remain within the predetermined tolerance.

LCP has been found to be a suitable material for housing 3 as it provides the following advantageous characteristics:
Robust.
Strong.
Easily mountable to a PCB.
Surface mountable to a PCB.
A high heat deflection temperature, in some grades of about 280° C.
A suitable dielectric constant.
Exceptionally low permeability, reportedly approaching that of glass because of their high degree of molecular organisation.
High thermal stability.
Low moisture absorption (less than 0.04%).
Good chemical resistance.
Relatively low cost.

The material of housing 3 is chosen based on the material having relatively high performance in one or more of the following criteria:
Thermal shielding—how well a material will deflect heat.
Thermal mass—how well a material will absorb and/or store heat.

It will be appreciated that LCP provides both high levels of thermal shielding and a high thermal mass. In other embodiments, however, housing 3 is constructed from other than LCP, or from LCP and other materials, some examples of which are discussed below.

Materials that are utilised in embodiments where the application requires relatively good thermal shielding properties include air, Nomex™ material (a meta-aramid material), silicone, and plastics (for example LCP), amongst others. Of these materials, Nomex™ material and plastics are often in sheet form and laminated or otherwise secured to define one or more external surface of housing 3. Silicone, however, is often coated to one or more of the interior or exterior surfaces of the housing, while air is typically used between layers in the housing, or between the housing and the supercapacitor 30. An example of the latter includes the voids 24 illustrated in the Figures. In other embodiments, such materials are included as intermediate layers within a laminate included within housing 3. In some embodiments, use is made of more than one of these materials for providing thermal shielding to supercapacitor 30.

The use of the above materials allows, in some embodiment, housing 3 to be constructed from other than LCP. However, it will be appreciated that in further embodiments these materials are used such that housing 3 is able to include a thinner LCP base, wall and/or sidewalls and yet ensure the performance characteristics for supercapacitor 30 remain within the required tolerances.

Materials that are utilised in embodiments where the housing requires relatively high thermal mass include silicone, epoxins, metals, and PCMs, amongst others. The use of these high thermal mass materials allows housing 3 to be constructed from other than LCP. However, it will be appreciated that in further embodiments these materials are used such that housing 3 is able to include a thinner LCP base, wall and/or sidewalls and yet ensure the performance characteristics for supercapacitor 30 remain within the required tolerances.

Housing 3 has a volumetric specific heat capacity of about 1 kJ/kg/K. In other embodiments where use is made of other LCP packaging or other materials it is possible to achieve other specific heat capacities. It has been found that for use with supercapacitors such as supercapacitor 30, that housing 3 should have a volumetric specific heat capacity of at least about 0.5 kJ/kg/K. In some embodiments—for example, where a high safety factor is required, or where the package is to be exposed to high temperatures or to elevated temperatures for longer durations—housing 3 has a higher volumetric specific heat capacity. In some such embodiments, the volumetric specific heat capacity is at least about 1.5 kJ/kg/K.

Those materials with a high thermal mass often also have a low thermal conductivity, where the latter is the rate of heat transfer through the material. For the present embodiments use is preferentially made of materials with a low thermal conductivity. In the FIG. 1 embodiment, housing 3 has a thermal conductivity of about 0.5 W/(mK). In other embodiments different materials provide for different thermal conductivities. It is preferred, however, that the thermal conductivity of the material is less than or equal to about 0.8 W/(mK). In an even more preferable embodiment, housing 3 has a thermal conductivity of no more than about 0.2 W/(mK).

To minimise the detrimental effect of the surface mounting of the device to the PCB, it is preferable to maintain interior 5 at relatively low temperatures. Housing 3 contributes to the maintenance of relatively low temperatures by:
Increasing the thermal capacity of the package.
Increasing the thermal barrier between the PCB and element 2.

More specifically, housing 3 of FIG. 1 contains the temperature within interior 5 to less than 200° C. during the surface mounting of the device to the substrate. In other embodiments housing 3 contains the temperature within interior 5 to less than 180° C. during the surface mounting of the device to the substrate. Preferably, where element 2 is a supercapacitor, the housing used contains the temperature within interior 5 to less than 230° C. during the surface mounting of the device to the substrate. It will be appreciated that the temperature within the interior is assessed at the interface with the supercapacitor, as this is the element being provided the thermal insulation.

In addition to heat transferring directly through the base, wall and sidewalls of housing 3 to interior 5, it will also transfer via leads 47 and 48. In the FIG. 1 embodiment, housing 3 and leads 47 and 48 are configured to provide thermal shielding and sufficient thermal mass to contain the temperature of terminals 37 and 38 below 200° C. during surface mounting of package 1 to the PCB. In other embodiments, more thermal shielding and thermal mass is provided by housing 3 and leads 47 and 48, and the temperature of terminals 37 and 38 is maintained below 180° C. during surface mounting of package 1 to the PCB. It is preferred for SMC such as supercapacitors that the temperature of terminals 37 and 38 is maintained below 230° C. during surface mounting of package 1 to the PCB.

One particular concern for supercapacitors during SMT processes is the temperature of the electrolyte. Most common electrolytes have a relatively low boiling point, generally less than 85° C., which is well below the temperatures of which SMC's are subjected to during manufacture. For these embodiments, housing 3 provides sufficient thermal mass and thermal shielding to maintain the temperature of the electrolyte well below its boiling point. As will be appreciated by those skilled in the art, the effect of the electrolyte reaching its boiling point is that gas will be produced within the sealed cavity of the supercapacitor. At best, this will highly compromise the capacitance and ESR of the supercapacitor. More typically, however, the gas produced will cause the sealed package of supercapacitor 30 to open and the supercapacitor to completely fail.

Use of one or more of the aforementioned suitable materials for housing 3 insulates element 2 against the heat associated with the SMT process. As mentioned above, this will ensure that the predetermined value of the predetermined electrical property remains within a predetermined tolerance. For supercapacitor 30, the key electrical properties include:
The capacitance of element 2 and its variance following the surface mounting process.
The equivalent series resistance (ESR) of element 2 its variance following the surface mounting process.
The operational life of element 2 and its variance following the surface mounting process.

For other SMC different electrical properties are used and different tolerances are achieved.

The above variances are references to tolerances that the predetermined electrical properties need to stay within to provide the required performance of the SMC, as connected in the circuit assembled on the PCB.

It will be appreciated by those skilled in the art, given the benefit of the teaching herein, that the predetermined tolerance is ±100% of at least one of the predetermined values. In a more preferable embodiment, the predetermined tolerance is ±50% of at least one of the predetermined values. In an even more preferable embodiment, the predetermined tolerance is ±20% of at least one of the predetermined values. In an even more preferable embodiment, the predetermined tolerance is ±10% of at least one of the predetermined values. It will be appreciated that as the number of predetermined values required to be maintained within respective tolerances rises, and as the value of the tolerances fall, there arises a greater need for housing 3 to provide increased insulation to element 2 during the SMT process.

In an embodiment where the electrical property of primary concern is the ESR of element 2, use is made of the package 1 of FIG. 1 to achieve a tolerance of the predetermined value of less than +20% over a wide range of initial ESR values. That is, the typical movement of ESR due to heat is upwardly, and the fmal ESR value is less than 20% greater than the initial ESR value. In that same embodiment, where the electrical property is the capacitance of element 2, the tolerance of the predetermined value of less than −20% over a wide range of initial capacitances. That is, the typical movement of capacitance due to heat is downwardly, and the fmal capacitance value is less than 20% less than the initial capacitance value.

In further embodiments, package 1 includes an additional thermal insulator for element 2. In some of those embodiments, element 2 is pre-coated with the thermal insulator prior to being received within the remainder of package 1. It has been found that suitable thermal insulators include a mixture of a high temperature PCM and a thermally insulating matrix. Examples of high temperature PCMs include sugar alcohols such as Mannitol and Dulcitol, although there are many others available, as would be appreciated by those skilled in the art. Examples of a thermally insulating matrix include silicone and epoxy, although other materials are also suitable.

Preferably, the selection of a PCM is based upon that material having a phase change just below the decomposition temperature of the most sensitive component within element 2. In the case of supercapacitors, the most sensitive component is often the electrode/electrolyte combination. For example, when the electrolyte used is EMITFB, the relevant temperature is just over 190° C. By way of a further example, when the electrolyte used is EMITFSI, the relevant temperature is about 220° C. By keeping the difference small between the relevant decomposition temperature and the phase change temperature, it is possible to minimise the amount of PCM required.

For the above examples of EMITFB and EMITFMS as electrolytes, the preferred PCM is Dulcitol. However, as the electrode/electrolyte thermal stability improves the preferred PCM will change to those with higher temperatures.

In practice, it has been found that the selection of the PCM is preferably based upon the phase change temperature being less than about 20° C. below the temperature where damage begins to the most sensitive or susceptible component or components. More preferably, the phase change temperature is less than about 10° C. below the temperature where damage begins to the most sensitive or susceptible component or components.

Other factors relevant to the selection of the PCM include:
Maximising the heat capacity per volume. (Specific heat and latent heat).
Minimising the heat conductivity.
Minimising deleterious side-effects, such as gas evolution, curing time, release of corrosive curing agents (acetic acid from the silicone), entrapped air;

It will be appreciated that the heat resistance of a material is the rate at which heat passes through the material, and is otherwise referred to as heat conductivity. The units are Watts per metre per degree Kelvin (W/m.K). Heat capacity, however, is the amount of heat that the material can absorb. This is a combination of the Specific Heat (or amount of heat required to heat 1 kg of the substance by 1 degree) and the latent heat (which is the amount of extra heat that the PCM absorbs when it goes through its phase transition). The units are kJ/kg/K. and kJ/kg, respectively.

| | Heat of Fusion | Phase change temperature | Specific Heat |
|---|---|---|---|
| PCM | (kJ/kg) | (° C.) | (kJ/kg/K) |
| Mannitol | 306 | 164 | 2.6 |
| Dulcitol | 352 | 189 | Unavailable |

As silicone is used in some embodiments, its properties, as that of the Aluminium terminal, are also relevant and indicative figures are provided below:

| | Specific Heat | Heat Conductivity |
|---|---|---|
| Material | (kJ/kg/K) | (W/m · K) |
| Silicone | 1.5 | 0.05 |
| Al terminal | N/A | 237 |

In the embodiments making use of a silicone/PCM mix, it has been found that a suitable ratio, by volume, of Si:PCM is about 1:1. In other embodiments different ratios are used.

The use of the PCM allows, in some embodiments, for the outer part of the package to provide primarily for structural strength, as the thermal properties are primarily provided by the PCM and/or other thermal insulator. Where the electrical device and/or SMT process requires, the outer part of the package is also designed to provide significant thermal properties. In still further embodiments, little or no outer packaging is used over the PCM:silicone mix.

As a basis for comparison, the following comparative test examples were carried out on embodiments of element 2 without housing 3.

### Comparative Example 1

Electrode sheets formed from 6 μm thick carbon coatings on 22 μm thick aluminium foil were layered with a 20 μm thick polypropylene separator to form a flat electrode stack with dimensions of about 30×15×1 mm and with terminals extending from opposite ends of the stack. Aluminium leads (5 mm wide and 100 μm thick) without pre-coatings were attached to the respective terminals. The whole was saturated with 1M TEATFB/AN electrolyte and sealed within a polypropylene and aluminium laminate package with an EAA sealant layer. The supercapacitor thus assembled had external dimensions of about 39×17×1.3 mm and the leads that extended about 15 mm from the supercapacitor. The supercapacitor, and a number of like supercapacitors, were heated from room temperature to about 50° C. over about eight minutes and then to 230° C. within two minutes, held at 230° C. for a further two minutes, and then air quenched back to room temperature. It was observed that, during heating, the packages puffed to the maximum extent the construction allowed and then seal failure occurred. In all cases the supercapacitors ceased to be effective supercapacitors due to high internal resistance and no measurable capacitance. Examination showed the separators had melted, the electrolyte had escaped and the electrodes were damaged.

### Comparative Example 2

Electrode sheets formed from 6 μm thick carbon coatings on 22 μm thick aluminium foil were layered with a 25 μm thick paper separator to form a flat electrode stack with dimensions about 30×15×1 mm and with terminals extending from opposite ends of the stack. Aluminium leads (5 mm wide by 100 μm thick) with pre-coated polypropylene sealant layers were attached to respective terminals. The whole was saturated with a substantially non-volatile electrolyte and sealed within a polypropylene and aluminium laminate package designed for packaging lithium-ion batteries. The supercapacitor thus assembled had external dimensions of about 39×17×1.3 mm and the leads that extended about 15 mm from the package. The supercapacitor, and a plurality of like constructed supercapacitors, were heated from room temperature to about 50° C. over about eight minutes and then to 230° C. within two minutes, held at 230° C. for a further two minutes, and then air quenched back to room temperature. It was observed that during heating the package did not substantially puff up, but became deformed and, in some cases, a visual inspection indicated that the seals had been compromised. In all cases the supercapacitors ceased to be effective supercapacitors due to extremely high internal resistance and no measurable capacitance. Careful examination showed the electrodes were damaged.

### Comparative Example 3

Supercapacitors similar to that in Comparative Example 2 were assembled where the electrolyte was an ionic liquid, including where the ionic liquid was one of: EMITFB; EMITFMS; EMITFSI; EMIDCA and Py_{1,3}TFSI. The supercapacitor, and a plurality of like constructed supercapacitors, were heated from room temperature to about 50° C. over about eight minutes and then to 230° C. within two minutes, held at 230° C. for a further two minutes, and then air quenched back to room temperature. It was observed that during heating the package did not substantially puff, but became [symbol] compromised. In all cases the supercapacitors ceased to be effective supercapacitors due to high internal resistance and no measurable capacitance. Careful examination showed the electrodes were damaged.

### Comparative Example 4

Assemblies similar to that in Comparative Example 2 were assembled where the separator was nylon ranging from about 20 μm to about 40 μm thick. The observations during and after SMT testing were substantially the same as for Comparative Example 2.

As evidence for maintaining a predetermined value within a predetermined tolerance through the use of housing 3, the following four examples of embodiments are included.

### EXAMPLE 1

Electrode sheets formed from 6 μm thick carbon coatings on 22 μm thick aluminium foil were layered with a 25 μm thick paper separator to form a flat electrode stack of maximum dimensions about 30×15×1 mm and with terminals extending from opposite ends of the stack. Aluminium leads (5 mm wide by 100 μm thick) with pre-coated polypropylene sealant layers were attached to respective terminals. The whole was saturated with EMITFB electrolyte and sealed within a polypropylene and aluminium laminate package designed for packaging lithium-ion batteries. The supercapacitor thus assembled has external dimensions of about 39×17×1.3 mm and the leads extended about 15 mm beyond the package. A thermocouple was attached to one lead at the edge of the laminate package. The supercapacitor was then approximately evenly coated with a thick layer (about 20 grams in total) of silicone sealant to give an approximately 50×28×15 mm device with the leads extending about 5 mm beyond the silicone layer. After curing overnight, the supercapacitor, and a plurality of like constructed supercapacitors, were heated from room temperature to about 50° C. over about eight minutes and then to 230° C. within two minutes, held at 230° C. for a further two minutes, and then air quenched back to room temperature. There was no externally obvious physical evidence of damage to the package. Electrical testing showed that after the simulated SMT exposure the ESR increased from 50 mΩ to about 115 mΩ and the capacitance decreased from about 0.55 F. to about 0.50 F. The thermocouple indicated that the lead adjacent to the package—that is, at the interface between the original package and the silicone layer—reached about 70° C. when the free end the lead initially reached 230° C. The thermocouple registered a continual increase in temperature as the supercapacitor remained exposed to 230° C. After 1 minute at 230° C. the thermocouple measured 123° C. and, after 2 minutes, 145° C. Even during the initial stages of air quenching, the temperature recorded by the thermocouple increased reaching a maximum of 160° C. about 20 seconds after quenching began.

### EXAMPLE 2

Supercapacitor cells similar to that in Example 1 were assembled with 100 mm long leads. Prior to coating with silicone these extended leads were folded against the package to extend the thermal path of the leads. Electrical testing of the devices thus formed showed that after the simulated SMT exposure the ESR of the supercapacitor increased from an initial 68 mΩ to about 135 mΩ, and that the capacitance had not changed.

### EXAMPLE 3

Electrode sheets formed from 6 μm thick carbon coatings on 22 μm thick aluminium foil were layered with a 25 μm thick paper separator to form a flat electrode stack of maximum dimensions about 30 ×15×1 mm and with terminals extending from opposite ends of the stack. Aluminium leads (3 mm wide by 100 μm thick and about 100 mm long) with pre-coated polypropylene sealant layers were attached to respective terminals. The whole was saturated with EMITFSA electrolyte and sealed within a polypropylene and aluminium laminate package designed for packaging lithium-ion batteries. The supercapacitor thus assembled has external dimensions of about 39×17×1.3 mm and the terminals extend approximately 100 mm. This supercapacitor cell was then placed within a housing machined from a 49×22×4 mm block of Teflon having a 45×18×2 mm cavity. The leads were folded to maximise the thermal pathway, with the free end of the leads extending about 7 mm from the housing. The remaining space within the cavity was then filled with Araldite LC191/LC177 epoxy, a Teflon lid (49×22×2 mm) was clamped on and the epoxy cured at 65° C. for one hour. The housing was then coated with an approximately 3 mm thick layer of silicone and allowed to cure overnight. The supercapacitor thus assembled was heated from room temperature to about 50° C. over about eight minutes and then to 230° C. within two minutes, held at 230° C. for a further two minutes, and then air quenched back to room temperature. There was no externally visible physical evidence of damage to the package. Electrical testing showed that after the simulated SMT exposure the ESR has increased from 79 mΩ to about 87 mΩ and the capacitance remained substantially the same.

### EXAMPLE 4

Electrode sheets formed from 15 μm thick carbon coatings on 22 μm thick aluminium foil were layered with a 35 μm thick nylon separator to form a flat electrode stack of maximum dimensions about 30×15×1 mm and terminals extending from opposite ends of the electrode stack. Aluminium leads (3 mm wide by 100 μm thick) with pre-coated polypropylene sealant layers were attached to the terminals. The whole was saturated with EMITFSA electrolyte and sealed within a polypropylene and aluminium laminate package designed for packaging lithium-ion batteries. The supercapacitor thus assembled has external dimensions of about 39×17×1.3 mm. This supercapacitor cell was then placed within an approximately 50×21×4 mm housing formed from a single folded sheet of Nomex™ material. The leads extended about 4 mm from the housing. The remaining space within the cavity was filled with Araldite LC191/LC177 epoxy, the housing was closed by folding a lid formed from the single sheet of Nomex™ material, clamping the housing and lid, and curing the epoxy through exposure to an elevated temperature of 65° C. for one hour. In some instances air was trapped within the housing. This housing was then wrapped in a single layer of 60 mm thick Kapton tape. The supercapacitor thus assembled was heated from room temperature to about 50° C. over about eight minutes and then to 230° C. within two minutes, held at 230° C. for a further two minutes, and then air quenched back to room temperature. Electrical testing showed that after the simulated SMT exposure the ESR has increased by about 20% from 73 mΩ and the capacitance was substantially unchanged at 1.2 F.

### EXAMPLE 5

A supercapacitor cell was constructed similarly to that of Example 1 above with a thermally stable separator of PTFE. (In other embodiments use is made of a Polyimide/polyamide separator). The cell was filled with a non-volatile electrolyte (EMITFSI). In other embodiments use is made of EMITFB or another ionic liquid. The cell was then hermetically packaged in a non-SMT rated package from which the terminals extend. In this example, the terminals are about 50 mm long and extend from one end of the non-SMT rated package and are folded back along that package. The cell and non-SMT rated package are coated in an additional thermal insulator having the form of a 1:1 by weight mixture of Mannitol: silicone. The coated cell is then packed into a two piece plastic housing (in this case constructed solely of PPS). The thermal insulator also acts as a sealant and adhesive between the two pieces of the plastic housing. The packaged cell is then ready to be passed through an SMT oven.

In other embodiments the cell is packed into a plastic housing of LCP.

In other embodiments, terminal leads are of a different length and/or differently configured. For example, in some embodiments, the terminal leads are wrapped around the cell. The intention is that the terminal leads provide for an increased thermal path while only protruding as far as required beyond the package.

In the above example, the silicone used was Dow Corning 734, a lower viscosity, self-levelling, high temperature siliCone.

It has been found that the combination of features provided in Example 5 provides a high yield of surface mounted supercapacitors having a capacitance that is at least 80% of the supercapacitor pre-surface mounting. Where the process is more tightly controlled, it is possible to obtain a high yield of supercapacitors having a capacitance that is at least 90% of the supercapacitor pre-surface mounting.

Moreover, the same supercapacitors will often have an ESR of no more than 110% of the ESR prior to surface mounting. In the more tightly controlled processes it is possible for those supercapacitors to have an ESR of no more than 108% of the ESR prior to surface mounting.

It will be appreciated by those skilled in the art, given the benefit of the teaching herein, that other phase change materials are also suitable. For example, for more challenging SMT oven profiles use is made of a PCM such as a higher temperature sugar. For example, Dulcitol (also known as Galacitol) which has a melting point of 189° C.

The more challenging oven profiles include those oven profiles having higher peak temperatures or longer durations at elevated temperatures. For example, some SMT ovens have peak temperatures of about 260° C., and in such cases, use is made of a higher melting point PCM, especially where the electrodes are able to withstand the lower ‘soak’ temperatures of 130 to 150° C.

Some of the other benefits of silicone as a matrix for the sugar PCM include:
It is compatible with a wide range of materials.
The mixture is able to be easily applied as a paste.
Formed bodies (such as sheets or shaped liners) are able to be made from the PCM/silicone mix and cured, and then subsequently assembled with the other components.
The PCM/silicone mix is able to be used as an adhesive to seal the external housing. One example includes pre-coating a two part package with the PCM/silicone mix, mounting the sealed supercapacitor cell inside one piece of the package, and bringing the other piece of the package into engagement with the first to form the package such that air and any excess mix is expelled from the package, and the remaining mix both fills any voids within the package and contributes to the seal between the two pieces of the package. In other embodiments use is made of an alternative or additional adhesive.

The preferred embodiments of the invention are particularly advantageously applied to electrical devices that are sensitive to thermal disruption during manufacture, or which are flexible and, hence, not suited to automated manufacture. The use of the embodiments allows such electrical devices to be relatively cheaply and effectively converted to respective SMC's that are suitably thermally and physically robust. The embodiments of the invention are also advantageously applied to making existing SMC's even more robust.

The above description provides numerous examples of the mounting of electrical devices to an insulator element that ensures one or more predetermined electrical properties of the device following surface mounting of the device is within a predetermined tolerance of the initial value.

In some embodiments the insulating element substantively encapsulates or envelops the electrical device, while in other embodiments the insulating element is simply disposed between the electrical element and the likely source of heat. Where there is encapsulation or envelopment of the electrical element, this is referred to in this specification as over-moulding. Some of the advantages of over-moulding include:
Improved hermeticity, where that is required.
Improved sealing, where that is required.
Improved rigidity—where, for example, an LCP housing is used—which aids automated handling.
Able to be “snapped-on” to the PCB.
Improved temperature resistance.
Only a small increase in footprint.
More reliable manufacture—that is, higher yields.

1 Contains the detrimental thermal affect on key characteristics of the electrical device.

For those embodiments where the electrical element is a supercapacitor, the containment of the reduction in the capacitance and the increase in the ESR also allows for containment of the required footprint of the supercapacitor for a given application.

For supercapacitors and other electrical devices that have their own packaging which is sealed, hermetically or otherwise, the package of the embodiments is able to be primarily directed to protecting that seal, rather than having to provide significant sealing properties in its own right. That is, the function of the over-moulding is to provide additional thermal or structural properties to the ultimate SMC, and to allow the electrical device to withstand the rigours of an SMT process. It has been found that where the sealing properties of the packaging for the electrical device is able to be maintained through the use of the embodiments, then this greatly contributes to the other electrical characteristics of the device being maintained within acceptable limits or tolerances.

The embodiments of the invention are intended for broad application to electronic devices in many technical fields. That is, once the one or more electrical device of the embodiment are mounted to a PCB, together with the other electrical devices, the PCB is mounted within an electronic device and connected as required to other components and/or other PCBs. Where the electrical device is a supercapacitor, the embodiments of the invention make that supercapacitor more easily incorporated into the manufacturing processes for:
Cellular telephones.
PC card/mini Peripheral Component Interconnect (PCI) cards/express card.
Universal Serial Bus (USB) applications.
Personal Digital Assistants (PDA's).
Voltage regulation module for computers.
Automatic meter reading/toll tags/Global Positioning System—General Packet Radio Service (GPS-GPRS) tracking.

It will be appreciated by those skilled in the art that many other applications are also available.

Other advantages available from the embodiments of the invention, particularly those constructed with LCR include.
Simple parts, leading to cost effective manufacturing.
Simple assembly steps.
Tight dimensional tolerances easily achievable.
No change in dimension of the housing within the usual SMT temperature range.
Applicable to reflow soldering.
Suitable for high volume manufacture (10′s of millions per month).
Suitable for high volume assembly.
Low cost.
Short time to implement
Thin housing, contributing to a relative small footprint and low profile.

While reference has been made above primarily to reflow soldering as the SMT process, in other embodiments an alternative SMT process is used. For example, such an alternative may be selected from:
IR reflow
Vapour phase reflow
Convection
Others including laser reflow, hot bar reflow wave soldering,

The above embodiments have been described to exemplify elements of the invention. It will be appreciated that while elements from any one embodiment are applicable to one or more other embodiments, such elements have been omitted from the drawings of those one or more other embodiments for the sake of clarity.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

Although the invention has been described with reference to specific examples, it will be appreciated by those skilled in the art that it may be embodied in many other forms. In particular, features of any one of the various described examples or embodiments may be provided in any combination in any of the other described examples or embodiments.

1-23. (canceled)

24. A package for an electrical device having an electrical property with a predetermined value, the package including an insulating element for supporting the device such that, following surface mounting of the device to a substrate, the predetermined value remains within a predetermined tolerance.

25. A package according to claim 24 wherein the electrical device includes packaging that is sealed and, following surface mounting of the device to the substrate, the packaging remains sealed.

26. A package according to claim 25 wherein the packaging is hermetically sealed and, following surface mounting of the device to the substrate, the packing remains hermetically sealed.

27. A package according to claim 24 wherein the electrical device includes: an energy storage device that is mounted to the insulating element; and at least two terminals that extend from the energy storage device, wherein the package includes at least two leads for electrically connecting the terminals with the substrate.

28. A package according to claim 27 wherein the energy storage device includes at least one supercapacitive element.

29. A package according to claim 28 wherein the insulating element is a housing having both an interior for containing the supercapacitive element and an exterior, wherein the leads extend from the interior to the exterior.

30. A package according to claim 28 wherein the electrical property is selected from the group including: equivalent series resistance (ESR) and capacitance (C).

31. A package according to claim 30 wherein the predetermined tolerance is ±100% of the predetermined value.

32. A package according to claim 30 wherein the predetermined tolerance is ±50% of the predetermined value.

33. A package according to claim 30 wherein the predetermined tolerance is ±20% of the predetermined value.

34. A package according to claim 30 wherein the predetermined tolerance is ±10% of the predetermined value.

35. A package according to claim 29 wherein the insulating element contains the temperature within the interior to less than 230° C. during the surface mounting of the device to the substrate.

36. A package according to claim 33 wherein the insulating element contains the temperature within the interior to less than 200° C. during the surface mounting of the device to the substrate.

37. A package according to claim 24 wherein the insulating element increases the thermal load of the device.

38. A package according claim 24 wherein the insulating element increases the thermal barrier between the substrate and the device.

39. A package according to claim 24 wherein the insulating element has a thermal conductivity of less than or equal to about 0.8 W/(mK).

40. A package according to claim 24 wherein the insulating element has a thermal conductivity of less than or equal to about 0.5 W/(mK).

41. A package according to claim 24 wherein the insulating element has a volumetric specific heat capacity of at least about 0.5 kJ/kg/K.

42. A package according to claim 24 wherein the insulating element has a volumetric specific heat capacity of at least about 1 kJ/kg/K.

43. An energy storage device having an electrical property with a predetermined value, the device including:
a supercapacitive element;
at least two terminals extending from the supercapacitive element; and
an insulating element for supporting the supercapacitive element such that, following surface mounting of the device to a substrate, the predetermined value remains within a predetermined tolerance.
